(19) United States
(12) Patent Application Publication
(10) Pub. No.: US 2004/0231495 A1
(43) Pub. Date: Nov. 25, 2004

(54) Digital music conversion device

(76) Inventors: Wen-Shan Huang, Sindian (TW); Chun-Lee Chiang, Taipei (TW); Tse-Hwa Hao, Taipei (TW); Shyh-Jie Yu, Yilan (TW); Yi-Ming Chen, Taipei (TW)

Correspondence Address: BIRCH STEWART KOLASCH & BIRCH, PO BOX 747, FALLS CHURCH, VA, 22040-0747, US

(21) Appl. No.: 10/725,415

(22) Filed: Dec. 3, 2003

(30) Foreign Application Priority Data
May 23, 2003 (TW) 092113959

(51) Int. Cl. H03M 1/00; G11C 5/00; G10H 7/00

(52) U.S. Cl. 84/601

(57) ABSTRACT

A digital music conversion device for converting digital music files in a first format into ones in a second format. The converted digital music files are stored in a portable recording medium. Using the disclosed conversion device, a digital music file in the first format that occupies a larger storage space is converted into one that occupies less space. Therefore, the latter can be stored in a portable storage medium. In comparison with the prior art, the invention does not need a computer to perform file format conversions and has simpler operations.

### BACKGROUND OF THE INVENTION

1. Field of Invention

The invention relates to a digital file conversion device and, in particular, to a digital music conversion device for music compact disk (CD) players.

2. Related Art

With the prevalence of Internet uses, the storage and transmissions of high quality sound data become more important in recent years. In order to reduce the storage space, data transmission time, the corresponding costs and the network bandwidths, many audio signal compression standards have been proposed and used. An example is the ISO MPEG 1 PART 3 (ISO/IEC 11172-3) standard, which defines three layers if coding. The coding method of the third layer (MPEG 1 Audio Layer 3) can reach a compression rate of 12:1 for both mono or stereo signals while still keeping the quality of music CD. The music file standard in the MP3 (MPEG Audio Layer 3) format is an audio signal compression method that only has a tiny quality loss. Therefore, it is widely accepted by the public. As the storage space it occupies is smaller than normal music or voice files, its use is also very popular on the Internet. Consequently, many MP3 players, recording devices and recording programs have been invented. However, existing digital music players, such as the MP3 walkman, require computers to convert the music files into the MP3 format before downloading them to the MP3 player. Since the procedure is rather complicated and the process has to be done by the computer user only, it is very inconvenient and impractical.

A digital walkman disclosed in the R.O.C. Pat. No. 339,179 is exactly a product under the above-mentioned idea. As shown in FIG. 1, the walkman body B is built with a microprocessor module 1, an MPEG 1 Audio Layer3 decoder module 2, a sound data file storage module 3, and a system control program 4. One side of the walkman body is provided with a printer port b1, a power switch, a headphone port, and a volume control (not shown). Its surface is comprised of a liquid crystal display (LCD) and a number of control keys. The personal computer (PC) is installed with a digital walkman device driver 5 and a music file management program 6. The printer port is the upload/download interface between the walkman body B and the PC. With a the printer cable and by executing the music file management program 6 on the PC, an MP3 sound file is downloaded to the walkman body B and stored in the memory card (not shown) in the sound data file storage module 3.

As described, this method has some inconveniences. For example, it requires the use of a computer along with a program. Therefore, it will be highly desirable if the files in a music CD can be converted into MP3 files without the use of a computer.

### SUMMARY OF THE INVENTION

In view of the foregoing, a primary objective of the invention is to provide a digital music conversion device that converts the music data on an optical recording medium into another format and stores the converted music data in a portable recording medium.

To achieve the above objective, the digital music conversion device is installed with a format converting module and a data transmission interface. The data transmission interface receives digital music files from a digital music player. The format converting module analyzes, decodes and converts the received digital music file. Through another data transmission interface, the converted digital music file is stored in a portable recording medium.

Since the conventional method is limited by the use of computers, it is very hard for the digital music files to become popular. The disclosed digital music conversion device, on the other hand, can achieve the digital music file format conversion without using a computer. Moreover, the invention can convert music files in a format that occupies a larger storage space into one that occupies less. For example, the storage space of a music CD with 10 songs is several hundreds of MB. Once converted into another format, such as MP3, ten songs only occupy tens of MB. Therefore, the files in the new format can be stored in a portable storage medium.

### BRIEF DESCRIPTION OF THE DRAWINGS

The invention will become more fully understood from the detailed description given hereinbelow illustration only, and thus are not limitative of the present invention, and wherein:

FIG. 1 is the system block diagram of a digital walkman in the prior art;

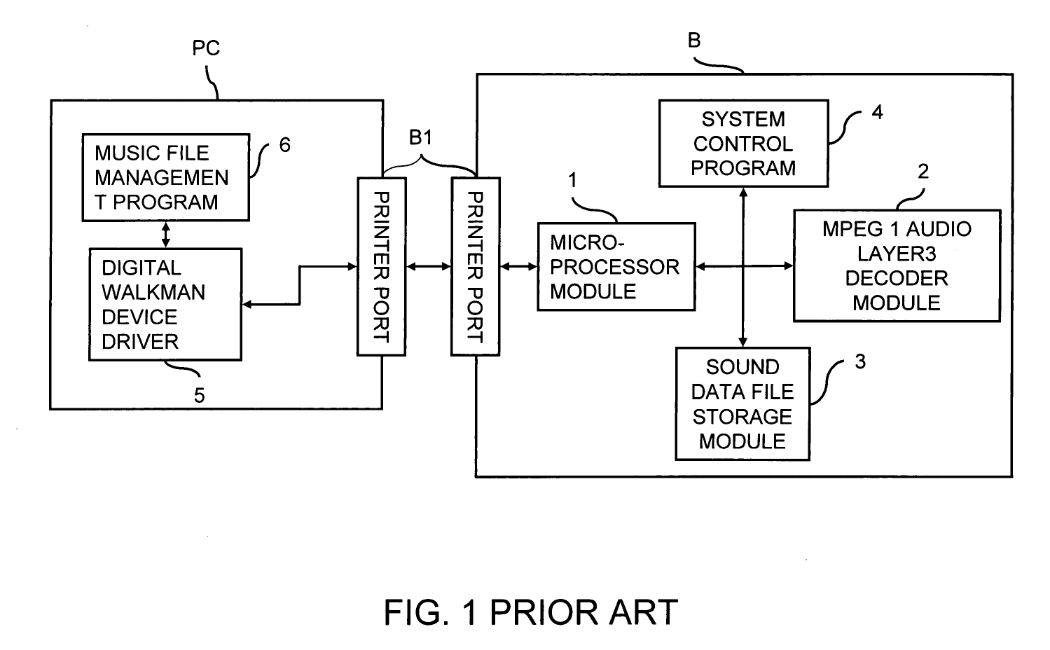

FIG. 2 shows a system structure of the disclosed digital music conversion device;

FIG. 3 is a module block diagram of the disclosed digital music conversion device;

FIG. 4 is a flowchart of the disclosed digital music conversion method; and

FIG. 5 is a second embodiment of the disclosed digital music conversion device.

### DETAILED DESCRIPTION OF THE INVENTION

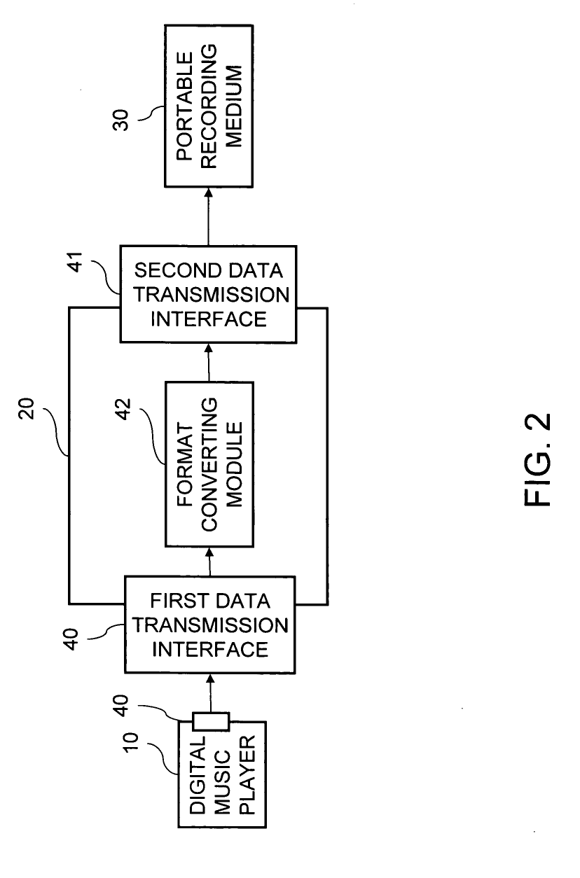

With reference to FIG. 2, the disclosed digital music conversion system has three major parts: the digital music player 10, the digital music conversion 20 and the portable recording medium 30. They are connected using first data transmission interfaces 40, 41 and a data transmission wire.

The digital music player 10 plays a recording medium stored with digital music files. The format of the digital music files is defined as the first format. The recording medium can be a CF memory card or a music compact disk (CD). If it is a music CD, the music file format used is the CDI format. The digital music player 10 can be a walkman, a stereo, a VCD player or any other player that plays music CD.

The digital music conversion device 20 is coupled to the digital music player 10 through a first data transmission interface 40 and a data transmission wire. The first data transmission interface 40 can be a universal serial bus (USB), an IEEE1394 bus, or an integrated device electronic (IDE) bus that support high-speed data transmissions. The user can plug a data transmission wire to the first data transmission interface 40 for the digital music conversion device 20 to receive the digital music files on the digital music player 10.

The digital music conversion device 20 analyzes, decodes, and converts a digital music file into another format after the file is received. More explicitly, the digital music conversion device 20 first checks whether the format of the received file is supported or defined by the user. If it is, then the digital music file is converted from the first format into the corresponding format, which is herein defined as the second format. The first format and the second format are two different formats. The converted digital music file in the second format is stored on the portable recording medium 30 via the second data transmission interface 41. The second format can be MP3, windows media audio (WMA), or advanced audio coding (AAC). In other words, the digital music file in the first format occupies a larger space than the one in the second format.

WMA is a new music format developed by Microsoft. It is usually only ⅓˜¼ of the size of the corresponding MP3 file. For example, a 4 MB MP3 file becomes only 1˜2 MB once converted into the WMA format.

AAC is a format that is more efficient than MP3 in compressing audio signals while still providing CD quality sounds. A 128 kbps stereo AAC file has almost the same audio quality as the original one. The AAC encoder/decoder are developed by the MPEG organization.

The portable recording medium 30 can be a PCMCIA card or flash memory card, such as the USB disk, the memory stick, the compact flash (CF) card, the multimedia card (MMC), the secure digital (SD) card, and the smart media (SM) card.

A primary feature of the invention is to convert a music file in the first format that is not portable into one in the second format using a music conversion device 20. The converted music file is stored in a portable recording medium 30. From the above description, one sees that the disclosed music conversion device 20 can perform music format conversions through a simple the connection with the digital music player 10 with a digital music recording medium. In comparison with the prior art, the invention is indeed much simpler and more convenient.

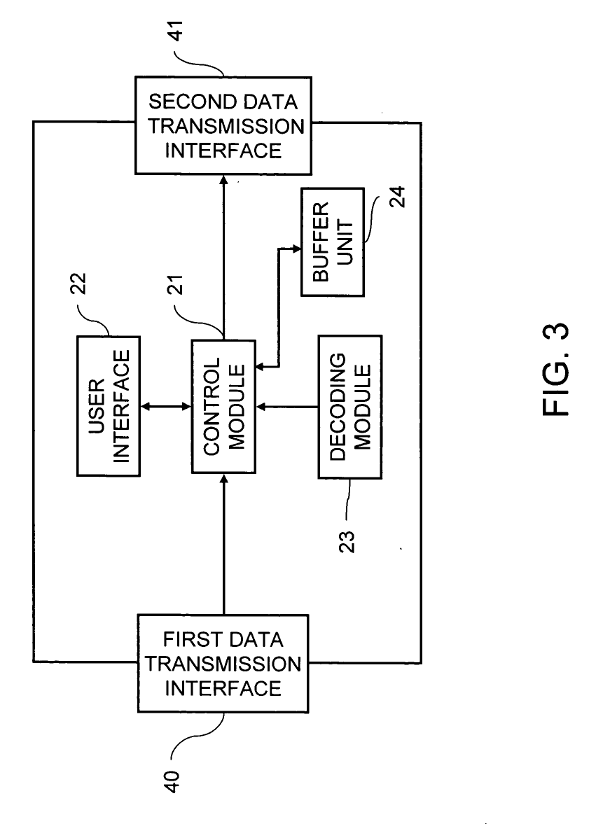

With use the module diagram of the digital music conversion device 20 in FIG. 3 to further explain the invention. In addition to the first data transmission interface 40, the second data transmission interface 41, the digital music conversion device 20 also uses a format converting module 42 to perform format analysis, decoding and conversion. The format converting module 42 includes a control module 21, a user interface (UI) 22, a decoding module 23, and a buffer unit 24. The UI 22, the decoding module 23, and the buffer unit 24 are all coupled to the control module. The control module 21 is connected to the first and second data transmission interfaces 40, 41 for receiving digital music files in the first format via the first transmission interface 40 and sending digital music files in the second format via the second transmission interface 41 to the portable recording medium 30 for storage. The control module 21 is preferably a digital signal processing (DSP) chip.

The UI 22 has several operation keys and a display monitor. The operation keys enable the user to control the device. The display monitor displays relevant messages during the operation process or the music format conversion process.

The decoding module 23 stores several digital music file formats, such as the MP3, WMA, and AAC formats, for decoding a digital music file in the first format according to the stored music file format. The buffer unit 24 helps the control module 21 to convert the format of the digital music file, speeding up the conversion.

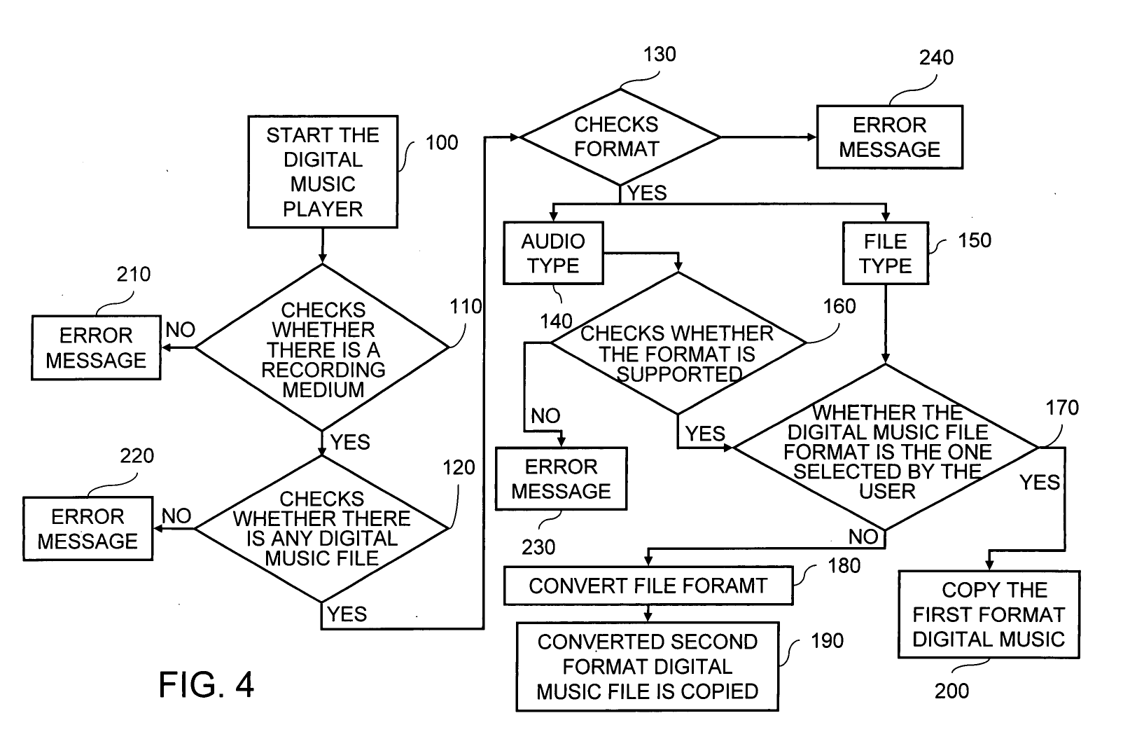

Finally, we describe the conversion procedure of the control module with reference to the flowchart shown in FIG. 4. After the digital music player 10 and the digital music conversion device 20 are connected using a transmission wire, the digital music player 10 is started (step 100). The control module 21 in the digital music conversion device 20 performs a series of checks for the music format to make sure that a music format conversion is possible.

First, the control module 21 checks whether there is a recording medium in the digital music player (step 110). If there is no recording medium, a corresponding error message is displayed in the UI 22 of the digital music conversion device 20 (step 210). If there is a recording medium, then it checks whether there is any digital music file stored on the recording medium (step 120). If there is no digital music file, a corresponding error message is displayed in the UI 22 of the digital music conversion device 20 (step 220). If there is a digital music file, then it checks whether its format is supported (step 130). If the format is not supported, a corresponding error message is displayed in the UI 22 of the digital music conversion device 20 (step 240).

The digital music file in the recording medium may be in two formats, the audio type and the file type. The digital music conversion device 20 performs different format conversions for these two types. If it is the audio type (step 140), it checks whether the format is supported by the system (step 160). If it is not supported, then a corresponding error message is displayed (step 230). If it is supported file type (step 150), then step 170 is executed. If the file on the recording medium is of the file type, then step 170 is executed immediately.

Step 160 compares the digital music file format on the recording medium with the file formats stored beforehand. If the decoding module 30 does not contain the corresponding file format, then the file cannot be converted using the disclosed digital music conversion device 20. Once the digital music file format is confirmed to be supported by the digital music conversion device 20, the conversion procedure can be started.

Step 170 determines whether the digital music file format detected by the system is the one selected by the user. If it is, then the first format digital music file is directly copied to the portable recording medium 30 for storage (step 200). If it is not, then the decoding module 23 converts the file format using the control module 21 and the buffer unit 24 (step 180). Finally, the converted second format digital music file is copied to the recording medium for storage (step 190).

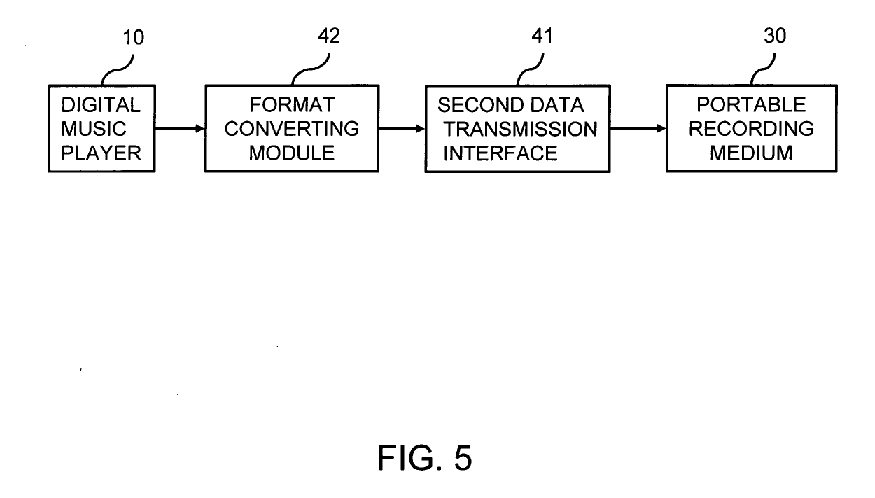

In the above-mentioned embodiment, the digital music player 10 and the digital music conversion device 20 are tow separate devices connected using a data transmission wire and a data transmission interface. A second embodiment of the invention is shown in FIG. 5. The digital music conversion device 20 is integrated inside the digital music player 10. All the user needs to do is insert the portable recording medium 30 into the digital music player 10. Through the connection of the second data transmission interface 41 and the operations of the keys on the digital music player 10, the first format digital music files in the digital music player 10 can be converted into files in the second format and stored in the portable recording medium.

Certain variations would be apparent to those skilled in the art, which variations are considered within the spirit and scope of the claimed invention.

What is claimed is:

1. A digital music conversion device for converting a digital music file in a first format into a digital music file in a second format, which comprises:
a first data transmission interface, which is connected to a digital music player via a data transmission wire, the digital music player is selectively loaded with a recording medium with the digital music file in the first format;
a format converting module, which is connected to the first data transmission interface for receiving the digital music file in the first format, and analyzing, decoding, and converting it into the digital music file in the second format so that the file in the second format occupies less storage space than the one in the first format; and
a second data transmission interface, which is connected to the format converting module and selectively to a portable recording medium that communicates with the second data transmission interface to store the digital music file in the second format in the portable recording medium.

2. The digital music conversion device of claim 1, wherein the format converting module further comprises:
a control module, which is coupled to the first data transmission interface and the second data transmission interface to receive and analyze the digital music file in the first format and to send the digital music file in the second format via the second data transmission interface to the portable recording medium for storage, respectively;
a decoding module, which is coupled to the control module and stored with a plurality of music formats for decoding the digital music file in the first format and converting it into the music file in the second format, the second format being one of the plurality of music formats; and
a buffer unit, which is coupled to the control module for assisting the operations of the control module and the decoding module.

3. The digital music conversion device of claim 1, wherein the format converting module further comprises a user interface (UI) with a plurality of operation keys and a display monitor, the operation keys enabling the user to control the device and the display monitor showing relevant messages during the operation process and the music format converting process.

4. The digital music conversion device of claim 1, wherein the control module is a digital signal processing (DSP) chip.

5. The digital music conversion device of claim 1, wherein the first data transmission interface is one selected from the group consisting of a high-speed data transmission interface, a PCMCIA interface, a universal serial bus (USB) interface, and an integrated device electronic (IDE) interface.

6. The digital music conversion device of claim 1, wherein the second data transmission interface is one selected from the group consisting of a high-speed data transmission interface, a PCMCIA interface, a universal serial bus (USB) interface, and an integrated device electronic (IDE) interface.

7. The digital music conversion device of claim 1, wherein the portable recording medium is one selected from the group consisting of a PCMCIA memory card and a flash memory card.

8. A digital music conversion device for converting a digital music file in a first format into a digital music file in a second format, which comprises:
a digital music player, which is selectively loaded with a recording medium containing digital music files in the first format; and
a format converting module, which is connected to the digital music player via a first data transmission interface for receiving a digital music file in the first format, and analyzing, decoding, and converting it into the digital music file in the second format so that the file in the second format occupies less storage space than the one in the first format;
wherein the format converting module is connected to a second data transmission interface, which is selectively connected to a portable recording medium that communicates with the second data transmission interface for storing the digital music file in the second format.

9. The digital music conversion device of claim 8, wherein the format converting module further comprises:
a control module, which is coupled to the first data transmission interface and the second data transmission interface to receive and analyze the digital music file in the first format and to send the digital music file in the second format via the second data transmission interface to the portable recording medium for storage, respectively;
a decoding module, which is coupled to the control module and stored with a plurality of music formats for decoding the digital music file in the first format and converting it into the music file in the second format, the second format being one of the plurality of music formats; and
a buffer unit, which is coupled to the control module for assisting the operations of the control module and the decoding module.

10. The digital music conversion device of claim 8, wherein the format converting module further contains a user interface (UI) with a plurality of operational keys and a display screen, the operational keys enabling the user to control and the display monitor showing relevant messages during operations/music format conversion processes.

11. The digital music conversion device of claim 8, wherein the control module is a digital signal processing (DSP) chip.

12. The digital music conversion device of claim 8, wherein the first data transmission interface is a high-speed data transmission interface.

13. The digital music conversion device of claim 12, wherein the first data transmission interface is a PCMCIA interface.

14. The digital music conversion device of claim 12, wherein the first data transmission interface is a universal serial bus (USB) interface.

15. The digital music conversion device of claim 8, wherein the first data transmission interface is an integrated device electronic (IDE) interface.

16. The digital music conversion device of claim 12, wherein the second data transmission interface is a high-speed data transmission interface.

17. The digital music conversion device of claim 16, wherein the second data transmission interface is a PCMCIA interface.

18. The digital music conversion device of claim 17, wherein the portable recording medium is a PCMCIA memory card.

19. The digital music conversion device of claim 8, wherein the second data transmission interface is a universal serial bus (USB) interface.

20. The digital music conversion device of claim 19, wherein the portable memory medium is a flash memory card.
